(19) United States
(12) Patent Application Publication
(10) Pub. No.: US 2012/0034553 A1
(43) Pub. Date: Feb. 9, 2012

(54) Photomask Blank, Photomask, and Pattern Transfer Method Using Photomask

(75) Inventors: Mitsuhiro Kureishi, Tokyo (JP); Hideaki Mitsui, Tokyo (JP)

(73) Assignee: Hoya Corporation

(21) Appl. No.: 13/272,988

(22) Filed: Oct. 13, 2011

Related U.S. Application Data
(63) Continuation of application No. 10/543,467, filed on Sep. 1, 2005.

(30) Foreign Application Priority Data
Feb. 3, 2003 (JP) JP2003-025485

(51) Int. Cl. G03F 1/00; G03F 1/50; G03F 1/26; G03F 7/20

(52) U.S. Cl. 430/5; 430/322

(57) ABSTRACT

A low reflective photomask blank suitable for shortened exposure wavelengths is disclosed. A photomask blank (1) having a single-layer or multilayer light-shielding film (3) arranged on a translucent substrate (2) and mainly containing a metal is characterized by comprising an antireflective film (6), which at least contains silicon and oxygen and/or nitrogen, on the light-shielding film (3).

### TECHNICAL FIELD

The present invention relates to a photomask used in manufacture of a semiconductor integrated circuit, a liquid crystal display apparatus or the like, a photomask blank which is an original plate of the photomask, and a pattern transfer method using the photomask.

### BACKGROUND ART

In manufacture of a semiconductor integrated circuit, a liquid crystal display apparatus or the like, a photolithography method using a photomask is utilized in a microfabrication process. As this photomask, one having a light-shielding film pattern on a translucent substrate forms a general configuration of a photomask called a binary mask. Further, in recent years, in order to realize highly accurate pattern exposure, there is a photomask called a phase shift mask. As the phase shift mask, there is known a currently practically utilized halftone type phase shift mask which has a semi-translucent phase shift film pattern on a translucent substrate and has a light-shielding film arranged on the semi-translucent phase shift film at a part which does not affect a phase shift effect of a non-transfer region of an outer peripheral portion of a transfer region having a transfer pattern or the transfer region in some cases. Besides, a practical application has been advancing with respect to a so-called a Levenson type phase shift mask which obtains a desired phase shift effect by carving a desired part on a translucent substrate having a light-shielding film pattern arranged thereon.

In case of using these photomasks in an exposure device such as a stepper, if a reflection factor of the photomask is high, light reflection is generated between a projection system lens of the stepper or a transfer target body and the photomask, a transfer accuracy of a pattern is consequently lowered due to an influence of multiple reflection, and hence a lower front surface reflection factor (and a lower rear surface reflection factor in some cases) of the photomask is preferable. Therefore, in the photomask, a thin film having a low reflection factor such as a light-shielding film formed on a translucent substrate is demanded, and a thin film with a high reflection factor must include an antireflective film. For example, in a light-shielding film consisting of a chrome-based material which forms a current main stream, it is general to provide an antireflective film consisting of chrome oxide on light-shielding chrome (see, e.g., “photomask gijutsu no hanashi (Story about Photomask Technology)” co-written by Isao Tanabe, Youichi Takehana and Morihisa Hougen, Kogyo Chosakai Publishing Inc., Aug. 20, 1996, pp. 80-81).

However, with higher integration or the like of a semiconductor integrated circuit in recent years, there is a viewpoint that a reduction in a pattern transfer accuracy due to an influence of multiple reflection between a photomask surface and a transfer target substrate becomes further serious, and hence a surface reflection factor of the photomask must be further reduced. As well known, an antireflective film utilizes weakening behaviors of reflected lights on front and rear surfaces of the antireflective film by an interferential action to reduce a reflection factor but, in a conventional antireflective film consisting of chrome oxide, light absorption is generated in an exposure wavelength, the reflected lights on the rear surface of the antireflective film are thereby reduced, and hence an antireflection effect cannot be satisfactorily obtained.

Furthermore, in order to cope with a demand for miniaturization and an improvement in a dimension accuracy of a pattern of a photomask owing to higher integration or the like of a semiconductor integrated circuit, shortening a wavelength of light from an exposure light source has been shifted from a current KrF excimer laser (a wavelength: 248 nm) to an ArF excimer laser (a wavelength: 193 nm) and an F2 excimer laser (157 nm), but there is a significant problem that the above-described antireflection effect cannot be sufficiently obtained as an exposure wavelength becomes shorter since light absorption occurs in the antireflective film consisting of chrome oxide as a wavelength becomes shorter.

Moreover, although a reduction in a reflection factor is demanded with respect to wavelengths of lights used in, e.g., an inspection apparatus for a defect or a foreign particle in a photomask or a photomask blank or a laser lithography apparatus when manufacturing a photomask in some cases, since these wavelengths also tend to be shortened, there is a problem that obtaining desired low reflection factor characteristics is becoming difficult.

### DISCLOSURE OF THE INVENTION

In order to eliminate the above-described problems, it is an object of the present invention to provide a photomask which can obtain a low reflection factor with respect an exposure wavelength corresponding to a shortened exposure wavelength in recent years of an ArF excimer laser (a wavelength: 193 mm), an F2 excimer laser (157 nm) or the like in particular, a photomask blank which is an original plate of the photomask, and a pattern transfer method using the photomask.

(Constitution 1) A photomask blank having a single-layer or multilayer light-shielding film which mainly contains a metal, on a translucent substrate, the photomask blank having an antireflective film, which at least contains silicon and oxygen and/or nitrogen, on the light-shielding film.
(Constitution 2) The photomask blank according to Constitution 1 or 2, wherein a surface reflection factor of the photomask blank is not greater than 10% in a desired wavelength selected from wavelengths shorter than a wavelength of 200 nm.
(Constitution 3) The photomask blank according to Constitution 1 or 2, wherein a reflection factor reducing film is provided between the light-shielding film and the antireflective film, the reflection factor reducing film consisting of a metal having a refraction factor larger than a refraction factor of a material constituting the light-shielding film and smaller than a refraction factor of a material constituting the antireflective film.
(Constitution 4) The photomask blank according to one selected from one selected from Constitutions 1 to 3, wherein the metal is selected from chrome, tantalum, tungsten, an alloy obtained from these metals and any other metal, and a material containing one or more of oxygen, nitrogen, carbon, boron and hydrogen in the metals or the alloy.
(Constitution 5) The photomask blank according to one selected from Constitutions 1 to 4, wherein a phase shift layer is provided between the translucent substrate and the light-shielding film.
(Constitution 6) The photomask blank according to one selected from Constitutions 1 to 5, wherein a surface reflection factor is not greater than 15% in a wavelength band of 150 nm to 300 nm.
(Constitution 7) The photomask blank according to one selected from Constitutions 1 to 5, wherein a surface reflection factor is not greater than 10% in a wavelength band of 150 nm to 250 nm.
(Constitution 8) A photomask manufactured by using the photomask blank according to one of Constitutions 1 to 7.
(Constitution 9) A pattern transfer method of performing pattern transfer by using the photomask according to Constitution 9.

### BRIEF DESCRIPTION OF THE DRAWINGS

FIG. 1 is a view showing a photomask blank manufactured in an embodiment;

FIG. 2 is a view showing a photomask manufactured in the embodiment;

FIG. 3 is views illustrating a manufacturing method of the photomask blank in the embodiment;

FIG. 4 is views illustrating the manufacturing method of the photomask in the embodiment;

FIG. 5 is a view showing reflection factor characteristics of photomask blanks manufactured in Embodiment 1 according to the present invention and Comparative Example 1;

FIG. 6 is a view showing characteristics of reflection factors of photomask blanks manufactured in Embodiment 2 and Embodiment 3 according to the present invention and Comparative Example 2; and

FIG. 7 is a view showing reflection factor characteristics of a photomask blank manufactured in Embodiment 4.

### BEST MODE FOR CARRYING OUT THE INVENTION

The present invention provides a photomask blank having a single-layer or multiplayer light-shielding film arranged on a translucent substrate and mainly containing a metal, the photomask blank characterized by having an antireflective film, which at least contains silicon and oxygen and/or nitrogen, on the light-shielding film.

According to the present invention, as the antireflective film of the photomask blank having the single-layer or multiplayer light-shielding film and mainly containing a metal, a material which at least contains silicon and oxygen and/or nitrogen, i.e., a material having high light permeability with respect to conventional chrome oxide in regularly used exposure wavelengths, various kinds of inspection wavelengths of the photomask or the photomask blank (e.g., wavelengths of 257 nm, 266 nm, 365 nm, 488 nm, 678 nm and others), or a wavelength band of 150 to 700 nm containing a lithography wavelength of the photomask is used, and hence adjusting an optical film thickness allows an interferential action of reflected lights on front and rear surfaces of the antireflective film to sufficiently weaken the lights, thereby obtaining the photomask blank having a low reflection factor (e.g., a reflection factor of 10% or below, or preferably 5% or below). Incidentally, it is preferable for the antireflective film to have a transmission factor of 70% or above in a desired wavelength, and a transmission factor of 80% or above is more preferable.

The present invention is particularly useful for obtaining an antireflection effect with respect to lights of 150 to 200 nm including exposure wavelengths such as an ArF excimer laser wavelength 193 nm or an F2 excimer laser wavelength 157 nm. That is because a current antireflective film consisting of a chromium compound cannot obtain a sufficient antireflection effect with respect to exposure wavelengths of, e.g., the ArF excimer laser or the F2 excimer laser whose wavelength is not greater than 200 nm.

In the present invention, the material of the antireflective film which at least contains silicon and oxygen and/or nitrogen may further contain at least one or more metal elements. In this case, since a transmission factor is reduced when a large quantity of metals is contained, using 20 at % or below of metals is preferable, and using 15 at % is more preferable.

Additionally, in the present invention, since the light-shielding film mainly contains a metal, it is possible to provide the light-shielding film which has excellent light-shielding properties and pattern processing performances. As a material of such a light-shielding film, there are chrome, tantalum, tungsten or an alloy formed of such metals and any other metal, and a material containing one or more of oxygen, nitrogen, carbon, boron and hydrogen in the metals or the alloy. It is to be noted that using chrome alone which is utilized in a conventional binary mask or a material containing one or more of oxygen, nitrogen, carbon and hydrogen in chrome can provide an advantage of using a pattern forming method in manufacture of an existing photomask blank or manufacture of a photomask, which is preferable.

In this case, when a material of the antireflective film is a light-shielding film material having resistance properties with respect to etching of a material of the light-shielding film at the time of forming a pattern in manufacture of the photomask, the antireflective film can be used as an etching mask for the light-shielding film, thereby improving etching processing properties of the light-shielding film. Specifically, a material containing silicon and oxygen and/or nitrogen which is a material of the antireflective film in the present invention is subjected to dry etching using a fluorine-based gas. On the other hand, a chrome-based material which is a material of the light-shielding film can be generally subjected to dry etching using a chlorine-based gas or wet etching using a chlorine-based etchant (cerium ammonic nitrate+perchloric acid), and a tantalum-based material can be also subjected to dry etching using a chlorine-based gas. Here, as the chlorine-based gas, there are Cl₂, BCl₃, HCl, a mixed gas of these materials, a gas containing O₂ or a noble gas (He, Ar, Xe) as an added gas in addition to these materials, and others. Further, as the fluorine-based gas, there are CₓF_{y} (e.g., CF₄, C₂F₆), CHF₃, a mixed gas of these materials, a gas containing O₂ or a noble gas (He, Zr, Xe) as an added gas in addition to these materials, and others. Furthermore, it is known that a system of these materials has high etching selectivity with respect to etching of these materials. Therefore, pattern processing properties can be improved by etching the antireflective film and then etching the light-shielding film with an antireflective film pattern being used as a mask as compared with a case of conventional etching in which a resist pattern is used as a mask.

Moreover, in a process of manufacturing a photomask or the like, it is preferable for reflection factor characteristics of the photomask to be entirely reduced in the vicinity of at least a specific wavelength rather than reduced in a specific wavelength only in some cases. That is because, even though a predetermined reflection factor reduction effect is obtained in a desired exposure wavelength, when a reflection factor steeply increases in the vicinity of this wavelength and exceeds a predetermined reflection factor, there is a possibility of occurrence of a problem that a large deviation from a design reflection factor (a steep increase in a reflection factor) is generated due to a fluctuation in a film composition or a film reduction produced when performing processing with respect to a mask, and a product having a deviation from the design reflection factor which is below standards is determined as a defective product, thereby lowering productivity. Additionally, in the process of manufacturing the photomask or the like, a case where reflection factor characteristics of the photomask are broadened and reduced in a wide wavelength band may be preferable as compared with a case where the reflection factor characteristics are reduced in the vicinity of a specific wavelength only. That is because an exposure wavelength, an inspection wavelength of an inspection device used for an inspection of a photomask and a laser wavelength of a laser photolithography device used for manufacture of a photomask are different from each other, and a high reflection factor may be a problem even in the inspection wavelength or the laser wavelength of the laser lithography device. Therefore, in the present invention, it is preferable to provide a reflection factor reducing film between the light-shielding film and the antireflective film, the reflection factor reducing film consisting of a material having a refraction factor larger than a refraction factor of a material constituting the light-shielding film and smaller than a refraction factor of a material constituting the antireflective film. With such a configuration, it is possible to provide a photomask blank whose surface reflection factor is broadened and reduced (entirely reduced) in a wide wavelength band.

Further, even if the antireflective film is a film whose reflection factor steeply increases in the vicinity of a desired exposure wavelength (e.g., a wavelength range of ±50 nm around a desired exposure wavelength (preferably a wavelength range of 36 nm) and exceeds a predetermined reflection factor (e.g., 15%), providing the reflection factor reducing film under the antireflective film can obtain an effect of supplementary reducing the reflection factor which Steeply increases in the vicinity of the desired exposure wavelength (which is specifically an effect of reducing the reflection factor to a predetermined reflection factor or a smaller factor, e.g., the reflection factor of 15% or below in the vicinity of the desired exposure wavelength). That is, this reflection factor reducing film also has an effect of further decreasing the reflection factor which has been basically reduced in the vicinity of a desired exposure wavelength by the antireflective film. It is to be noted that this reflection factor reducing film is set to have an optical film thickness with which the reflection factor is reduced to some extent, and the antireflective film has a higher transmission factor than that of this reflection factor reducing film in a desired wavelength with which a low reflection factor is demanded.

As the photomask blank whose surface reflection factor is broadened and reduced (entirely reduced) in a wide wavelength band, specifically, setting the surface reflection factor to 15% or below in a wavelength band of 150 nm to 300 nm can cope with not only exposure light obtained by, e.g., a KrF excimer laser, an ArF excimer laser or an F2 excimer laser but also inspection light in a manufacturing process or the like, and the productivity of the mask can be improved, which is preferable. Further, when the surface reflection factor is set to 10% or below in a wavelength band of 150 nm to 250 nm, one film configuration or a every similar film configuration can cope with all exposure lights obtained by the KrF excimer laser, the ArF excimer laser or the F2 excimer laser, thereby greatly reducing a cost.

Here, as a material of the reflection factor reducing film, there is a metal containing oxygen and, for example, there is chrome containing oxygen which is used for an antireflective film in a conventional photomask blank.

In the present invention, each of the light-shielding film, the reflection factor reducing film and the antireflective film may be a single-layer or multilayer film, and may be a film having a uniform composition or a composition gradient film in which a composition is sequentially modulated in a film thickness direction.

In the present invention, an antireflective film may be further provided between the translucent substrate and the light-shielding film. With such a configuration, an influence of multiple reflection on a mask rear surface side (a translucent substrate side) generated in exposure can be further effectively suppressed.

In the present invention, a manufacturing method of the photomask blank is not restricted. Manufacture is possible by using a sputtering apparatus which is of an inline type, a sheet type, a batch type or the like, and all the films on the translucent substrate can be of course formed by using the same apparatus or a combination of a plurality of apparatuses.

Moreover, the light-shielding film in the present invention may be a light-shielding film used in a phase shift mask. That is, the present invention may have a phase shift layer between the translucent substrate and the light-shielding film. The phase shift layer may consist of a material which is transparent or a material which is semitransparent with respect to exposure light.

It is to be noted that the light-shielding film in a halftone type phase shift mask blank in which the phase shift layer is formed of a semitransparent material have a film composition and a film thickness in such a manner that a desired light-shielding effect can be demonstrated in combination with the semitransparent phase shift layer.

A manufacturing method of the photomask produced by using the photomask blank according to the present invention is not restricted to a particular method such as a dry etching method or a wet etching method.

By performing pattern transfer using the photomask, an influence of multiple reflection between a projection system lens of a stepper or a transfer target body and the photomask can be greatly suppressed even in case of performing exposure by using short-wavelength light, thereby enabling transfer of a pattern with a high accuracy (enabling a reduction in transfer defects of a pattern). Embodiments according to the present invention will now be described hereinafter with reference to the accompanying drawings.

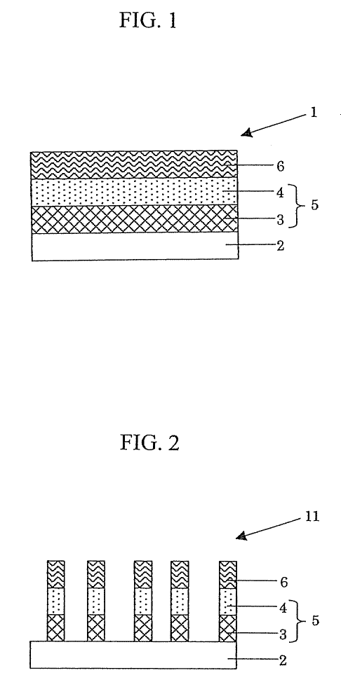

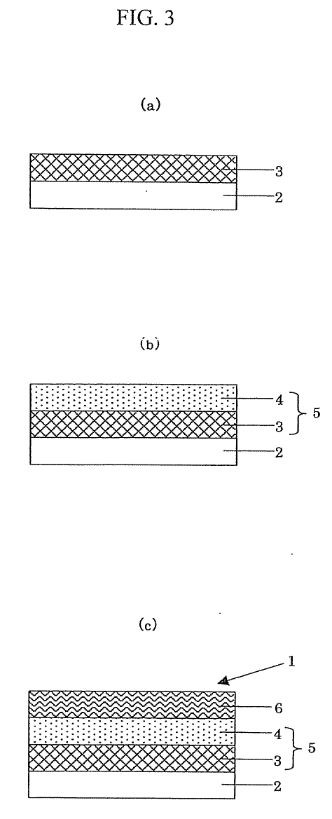

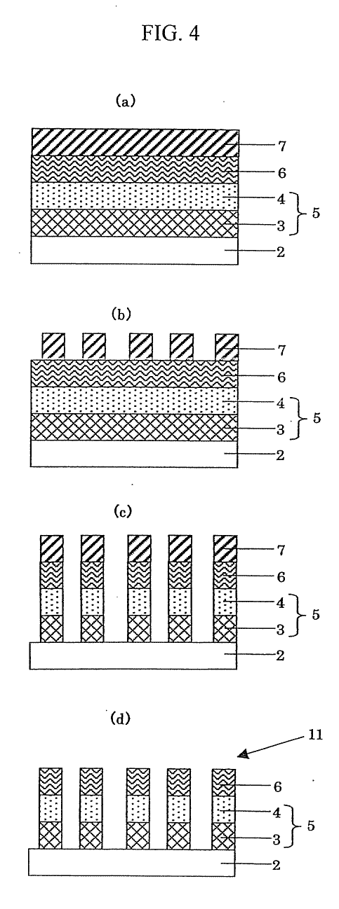

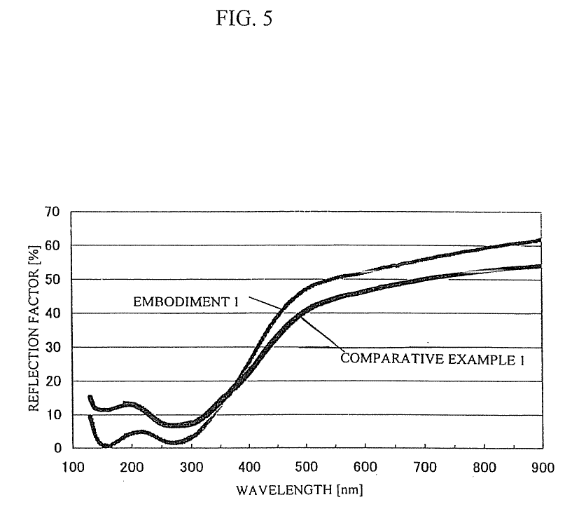

FIG. 1 is a cross-sectional view showing a photomask blank, FIG. 2 is a cross-sectional view showing a photomask, FIG. 3 is views illustrating a manufacturing method of the photomask blank, and FIG. 4 is views illustrating a manufacturing method of the photomask. Further, FIGS. 5 to 7 are views illustrating reflection factor characteristics of photomask blanks obtained in embodiments and comparative examples.

### Embodiment 1

As shown in FIG. 1, in a photomask blank 1 according to Embodiment 1, a quartz glass substrate having both main surfaces and end surfaces subjected to precision polishing and a size of 6 inches×6 inches×0.25 inch is used as a translucent substrate 2.

On the translucent substrate 2, a Cr film of 500 angstrom is formed as a light-shielding film 3, a CrO (which means that chrome and oxygen are contained but does not specify content rates of these materials, and this is also applied to the following) film of 180 angstrom is formed as a reflection factor reducing film 4 and an MoSiON film of 100 angstrom is formed as an antireflective film 6.

FIG. 2 is a cross-sectional view showing a photomask according to Embodiment 1. This photomask 11 is formed by sequentially patterning the antireflective film 6, the reflection factor reducing film 4 and the light-shielding film 3 from an upper layer portion of the photomask blank 1.

A manufacturing method of the photomask blank 1 will now be described with reference to FIG. 3.

First, a quartz glass substrate having both main surfaces and end surfaces subjected to precision polishing and a size of 6 inches×6 inches×0.25 inch was used as the translucent substrate 2, and a Cr film having a film thickness of 500 angstrom was formed as the light-shielding film 3 as shown in FIG. 3(a) by a sheet type sputtering apparatus using a Cr target in an Ar gas atmosphere (a pressure: 0.09 [Pa]).

Then, a CrO film (Cr corresponds to 40 atom %, and O corresponds to 60 atom %) having a film thickness of 180 angstrom was formed as the reflection factor reducing film 4 as shown in FIG. 3(b) by reactive sputtering using a Cr target in a mixed gas atmosphere (Ar: 70 volume %, O2: 30 volume %, and a pressure: 0.14 [Pa]) of Ar and O2.

Subsequently, an MoSiON film having a film thickness of 100 angstrom was formed as the antireflective film 6 as shown in FIG. 3(c) by reactive sputtering using an MoSi (Mo: 10 atom %, and Si: 90 atom %) target in a mixed gas atmosphere (Ar: 25 volume %, N2: 65 volume %, O2: 10 volume %, and a pressure: 0.14 [Pa]) of Ar, N2 and O2. Then, scrub cleansing was performed, thereby obtaining the photomask blank 1.

Here, a transmission factor of the MoSiON film of 100 angstrom used as the antireflective film was 91.7% in 248 nm and 86.7% in 193 nm, and a transmission factor of the CrO film of 180 angstrom used as the reflection factor reducing film was 34.6% in 248 nm and 23.0% in 193 nm (however, a transmission factor of the quartz substrate having a thickness of 6.35 mm is included in this example). That is, the antireflective film has light permeability higher than that of the reflection factor reducing film in all exposure light wavelengths obtained by a KrF excimer laser and an ArF excimer laser.

A reflection factor of the obtained photomask blank 1 was less than 10% in a wide wavelength band of 150 nm to 300 nm as shown in FIG. 5.

A vacuum ultraviolet spectroscope (VU 210) manufactured by Bunko-Keiki Co., Ltd. and an n&k analyzer 1280 manufactured by n&k Inc. were used for measurement of these transmission factors and reflection factors.

A manufacturing method of the photomask 11 will now be described with reference to FIG. 4.

First, as shown in FIG. 4(a), a resist 7 was applied on the antireflective film 6. Then, a resist pattern 7 was formed by pattern exposure and development as shown in FIG. 4(b).

Subsequently, exposed MoSiON as the antireflective film 6 was removed by dry etching using a mixed gas of CF4 and O2 as an etching gas with the resist pattern being utilized as a mask as shown in FIG. 4(c), and then the exposed CrO film as the reflection factor reducing film 4 and the Cr film as the light-shielding film 3 were sequentially removed by dry etching using a mixed gas of Cl2 and O2 as an etching gas.

Thereafter, the resist 7 was peeled off by a regular method using oxygen plasma or sulfuric acid, thereby obtaining the photomask 11 having a desired pattern as shown in FIG. 4(d). A positional accuracy of the mask pattern in the obtained photomask 11 was measured, and a result was the same as a set value and very excellent.

It is to be noted that the description has been given as to the example of film formation by a reactive sputtering method using the sheet type sputtering apparatus in Embodiment 1, but the sputtering apparatus is not restricted. For example, the present invention can be applied to reactive sputtering using an inline type sputtering apparatus, a method of forming a film in a batch mode based on the reactive sputtering method with a sputtering target being arranged in a vacuum chamber.

Moreover, although dry etching was performed by using the mixed gas of CF4 and O2 and the mixed gas of Cl2 and O2 in Embodiment 1, types of gases to be used can be appropriately determined. For example, it is possible to employ a method using a chlorine-based gas or a gas containing chlorine and oxygen with respect to all the films, or perform dry etching using a fluorine-based gas or a gas containing fluorine and oxygen with respect to the antireflective film and then carry out etching using a gas containing chlorine or a gas containing chlorine and oxygen with respect to the reflection factor reducing film and the light-shielding film. Additionally, a wet etching method can be also used.

### Embodiment 2

First, a translucent substrate 2 having a size of 6 inches×6 inches×0.25 inch obtained by subjecting main surfaces and end surfaces (side surfaces) of a quartz substrate to precision polishing was used, and a CrC film as a light-shielding film (layer), 3 was formed by reactive sputtering of an inline type sputtering apparatus using a Cr target in a mixed gas atmosphere of Ar and CH4 (Ar: 96.5 volume %, CH4: 3.5 volume %, and a pressure: 0.3 [Pa]).

Then, a CrON film as a reflection factor reducing film (layer) 4 was formed on the light-shielding film (layer) by reactive sputtering of the same inline type sputtering apparatus using a Cr target in a mixed gas atmosphere of Ar and NO (Ar: 87.5 volume %, NO: 12.5 volume %, a pressure: 0.3 [Pa]). Here, formation of the CrON film was carried out continuously with formation of the CrC film, and a total film thickness of the CrON film and the CrC film was 800 angstrom. This corresponds to a case where a boundary between the light-shielding film (layer) and the reflection factor reducing film (layer) is not clear but it is possible to substantially recognize a laminated layer of the light-shielding film (layer) and the reflection factor reducing film (layer).

Then, an SiN film having a film thickness of 50 angstrom was formed as an antireflective film 6 by reactive sputtering of a sheet type sputtering apparatus using an Si target in a mixed gas atmosphere of Ar and N2 (Ar: 50 volume %, N2: 50 volume %, and a pressure: 0.14 [Pa]). Then, scrub cleansing was carried out to obtain a photomask blank 1.

Here, a transmission factor of the 50-angstrom SiN film used as the antireflective film was 91.8% in 248 nm and 84.8% in 193 nm (however, a transmission factor of the quartz substrate having a film thickness of 6.35 mm is included in this example).

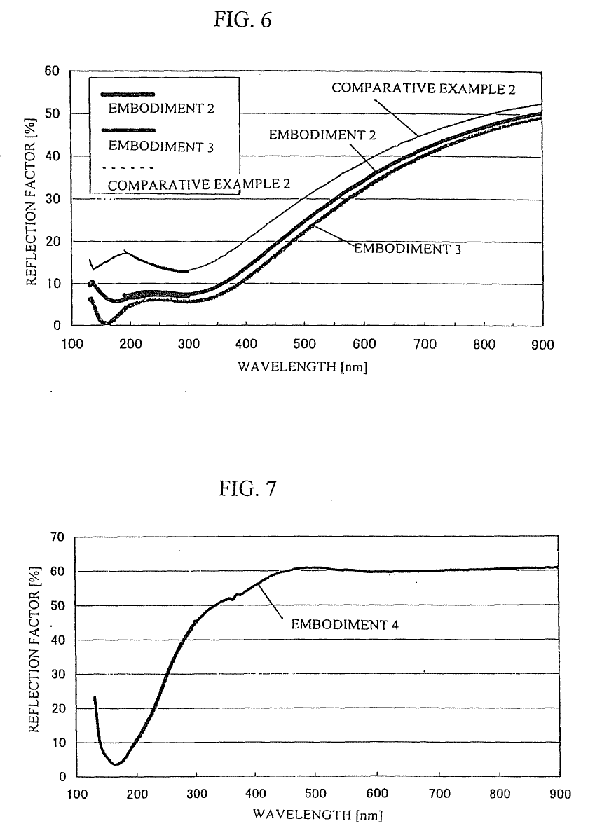

A reflection factor of the obtained photomask blank 1 was measured, and a result was less than 10% in a wide wavelength band of 150 nm to 300 nm as shown in FIG. 6.

### Embodiment 3

First, a quartz glass substrate having both main surfaces and end portions subjected to precision polishing and a size of 6 inches×6 inches×0.25 inch is used as a translucent substrate 2, then a CrC film (layer) as a light-shielding film 3 and a CrON film as a reflection factor reducing film (layer) 4 are continuously formed, and these steps are the same as those in Embodiment 2.

Subsequently, an MoSiON film having a film thickness of 100 angstrom was formed as an antireflective film 6 by reactive sputtering of a sheet type sputtering apparatus using an MoSi (Mo: 10 atom %, and Si: 90 atom %) target in a mixed gas atmosphere of Ar, N2 and O2 (Ar: 25 volume %, N2: 65 volume %, O2: 10 volume %, and a pressure: 0.13 [Pa]). Thereafter, scrub cleansing was performed to obtain a photomask blank 1.

Here, a transmission factor of the 100-angstrom MoSiON film used as the antireflective film was 91.7% in 248 nm and 86.7% in 193 nm like Embodiment 1 (however, a transmission factor of the quartz substrate having a thickness of 6.35 mm is included in this example).

A reflection factor of the obtained photomask blank 1 was measured, and a result was less than 10% in a wide wavelength band of 150 nm to 300 nm as shown in FIG. 6.

Comparative Example 1, Comparative Example 2 and Reference Example 1 will now be described. Each of Comparative Example 1 and Comparative Example 2 is a conventionally used photomask blank, namely, a structure in which the “antireflective film” as an essential configuration of the present invention is eliminated from the photomask blank of each of Embodiments 1 to 3.

### Comparative Example 1

A quartz glass substrate having both main surfaces and end surfaces subjected to precision polishing and a size of 6 inches×6 inches×0.25 inch was used as a translucent substrate 2, a Cr film having a film thickness of 500 angstrom as a light-shielding layer 3 and a CrO film having a film thickness of 180 angstrom as a reflection factor reducing film 4 were formed based on the same procedure as that of Embodiment 1, and then scrub cleansing was carried out, thereby obtaining a photomask blank 1. That is, Comparative Example 2 is a structure in which the “antireflective film 6” as an essential configuration of the present invention is eliminated from the photomask blank according to Embodiment 1.

A reflection factor of the obtained photomask blank 1 was higher than 10% in a wavelength band of 150 nm to 300 nm as shown in FIG. 5.

### Comparative Example 2

A quartz glass substrate having both main surfaces and end surfaces subjected to precision polishing and a size of 6 inches×6 inches×0.25 inches was used as a translucent substrate 2, a CrC film as a light-shielding film (layer) 3 and a CrON film as a reflection factor reducing film (layer) 4 were continuously formed based on the same procedure as those of Embodiment 2 and Embodiment 3 so that a total film thickness of 800 angstrom can be obtained, and then scrub cleansing was carried out, thereby obtaining a photomask blank 1. That is, Comparative Example 2 is the structure in which the “antireflective film 6” as an essential configuration of the present invention is eliminated from the photomask blank according to Embodiments 2 and 3.

A reflection factor of the obtained photomask 1 was higher than 10% in a wavelength band of 150 nm to 300 nm as shown in FIG. 6.

### Embodiment 4

A quartz glass substrate having both main surfaces and end surfaces subjected to precision polishing and a size of 6 inches×6 inches×0.25 inch was used as a translucent substrate 2, a Cr film having a film thickness of 500 angstrom was formed as a light-shielding film 3, an SiNx film having a film thickness of 60 angstrom was formed as an antireflective film 6 directly on the Cr film like Embodiment 1, and then scrub cleansing was carried out, thereby obtaining a photomask blank 1. That is, Embodiment 4 is a structure in which the “reflection factor reducing film 4” is eliminated from the photomask blank according to Embodiment 1.

In regard to a reflection factor of the obtained photomask blank 1, as shown in FIG. 7, a predetermined reflection factor (approximately 40% in this example) can be obtained with respect to a desired exposure wavelength (a wavelength of an F2 excimer laser in this case: 157 nm). However, it can be understood than the reflection factor steeply increases as compared with Embodiment 1.

It is to be noted that FIG. 7 shows the example where the reflection factor with respect to the wavelength of the F2 excimer laser is reduced, there is the same tendency as that of FIG. 7 in a case where the reflection factor with respect to a wavelength of an ArF excimer laser: 193 nm is reduced. Further, in case of an Si-based antireflective film/metal light-shielding film, the same tendency as that of FIG. 7 can be demonstrated irrespective of materials of these films.

It is to be noted that the present invention is not restricted to the foregoing embodiments.

For example, a fluorine-doped quartz glass substrate, a calcium fluoride substrate or the like can be used in place of the quartz glass substrate in accordance with an exposure wavelength.

According to the present invention, with the configuration in which the antireflective film which at least contains silicon and oxygen and/or nitrogen is provided on the single-layer or multilayer light-shielding film mainly containing a metal, reflection on surfaces generated when performing exposure with a short-wavelength light can be effectively suppressed, thereby realizing provision of the photomask blank and the photomask having the light-shielding film with the antireflective film having sufficient light-shielding performances.

1-9. (canceled)

10. A photomask blank being used for manufacturing a photomask at an exposure wavelength band of not greater than 200 nm, comprising:
a translucent substrate,
a single-layer or multilayer light-shielding film whose main constituent is a metal, on the translucent substrate, and
an antireflective film, which contains a silicon and at least one of oxygen and nitrogen, on the light-shielding film,
wherein the light-shielding film is made of a material having resistance properties to etching with respect to the antireflective film.

11. The photomask blank according to claim 10, wherein the light-shielding film is made of a material subjected to dry etching using a chlorine-based gas and the antireflective film is made of a material subjected to dry etching using a fluorine-based gas.

12. The photomask blank according to claim 10, wherein the metal contained in the light-shielding film is selected from tantalum, an alloy obtained from the tantalum and any other metal, and a material containing one or more of oxygen, nitrogen, carbon, boron and hydrogen in the tantalum or the alloy.

13. The photomask blank according to claim 10, wherein the metal contained in the light-shielding film is selected from chrome, an alloy obtained from the chrome and any other metal, and a material containing one or more of oxygen, nitrogen, carbon, boron and hydrogen in the chrome or the alloy.

14. The photomask blank according to claim 10, wherein the metal contained in the light-shielding film is selected from tungsten, an alloy obtained from the tungsten and any other metal, and a material containing one or more of oxygen, nitrogen, carbon, boron and hydrogen in the tungsten or the alloy.

15. The photomask blank according to claim 10, wherein the antireflective film contains a metal.

16. The photomask blank according to claim 10, further comprising: a reflection factor reducing film provided between the light-shielding film and the antireflective film, wherein the reflection factor reducing film is made of a material having resistance properties to etching with respect to the antireflective film.

17. The photomask blank according to claim 10, further comprising: a reflection factor reducing film provided between the light-shielding film and the antireflective film, wherein the reflection factor reducing film consists of a material having a refraction factor smaller than a refraction factor of a material constituting the antireflective film.

18. The photomask blank according to claim 10, further comprising: a reflection factor reducing film provided between the light-shielding film and the antireflective film, wherein the reflection factor reducing film consists of a material having a refraction factor smaller than a refraction factor of a material constituting the antireflective film, a surface reflection factor of the photomask blank being not greater than 15% in a wavelength band of 150-300 nm.

19. The photomask blank according to claim 10, further comprising: a reflection factor reducing film provided between the light-shielding film and the antireflective film, wherein the reflection factor reducing film consists of a material having a refraction factor smaller than a refraction factor of a material constituting the antireflective film, a surface reflection factor of the photomask blank being not greater than 10% in a wavelength band of 150-250 nm.

20. The photomask blank according to claim 10, further comprising: a reflection factor reducing film provided between the light-shielding film and the antireflective film, wherein the reflection factor reducing film consists of a material having a refraction factor larger than a refraction factor of a material constituting the light-shielding film and smaller than a refraction factor of a material constituting the antireflective film.

21. The photomask blank according to claim 16, wherein the reflection factor reducing film contains a chrome.

22. The photomask blank according to claim 16, wherein a transmission factor of the antireflective film is greater than 70% in a wavelength band of not greater than 200 nm and larger than a transmission factor of the reflection factor reducing film.

23. The photomask blank according to claim 10, further comprising: a phase shift layer provided between the translucent substrate and the light-shielding film.

24. A photomask manufactured by using the photomask blank according to claim 10.

25. A pattern transfer method of performing pattern transfer by using the photomask according to claim 24.
